(19) United States
(12) Patent Application Publication
(10) Pub. No.: US 2015/0303152 A1
(43) Pub. Date: Oct. 22, 2015

(54) SEMICONDUCTOR PACKAGE AND SEMICONDUCTOR MODULE INCLUDING THE SAME

(71) Applicant: Murata Manufacturing Co., Ltd., Kyoto (JP)

(72) Inventors: Masamichi TOKUDA, Kyoto (JP); Ryangsu KIM, Kyoto (JP); Naru MORITO, Kyoto (JP)

(21) Appl. No.: 14/659,664

(22) Filed: Mar. 17, 2015

(30) Foreign Application Priority Data
Apr. 16, 2014 (JP) 2014-084913
Nov. 17, 2014 (JP) 2014-232958

(51) Int. Cl. H01L 23/552; H01L 23/00; H01L 23/498; H01L 23/31

(52) U.S. Cl. CPC H01L 23/552; H01L 23/3107; H01L 24/49; H01L 23/49838; H01L 2224/48106; H01L 2224/48227; H01L 2924/14; H01L 2924/1511; H01L 2924/1517; H01L 2924/01014; H01L 2924/10253

(57) ABSTRACT

A semiconductor package includes the following elements. A high-output switch IC includes an IC top surface on which an electrode is disposed and an IC bottom surface on which no electrode is disposed. A connecting terminal is formed at a position outside a projection region toward a side portion of the semiconductor package. The projection region is a region projected in a thickness direction of the high-output switch IC. A wire electrically connects the electrode and the connecting terminal. A mold resin section covers the IC top surface and the wire and also covers a surface of the connecting terminal to which the wire is connected. A surface of the connecting terminal opposite to the surface to which the wire is connected is not covered with the mold resin section but is exposed. The IC bottom surface is not covered with a metal.

### BACKGROUND OF THE INVENTION

1. Field of the Invention

The present invention relates to a semiconductor package and a semiconductor module including this semiconductor package.

2. Description of the Related Art

Japanese Unexamined Patent Application Publication No. 2007-5477 discloses an invention which aims to eliminate noise components of a device in which an integrated circuit (IC) fixed on a ball grid array (BGA) substrate, which is called an interposer, is mounted on a motherboard. The invention disclosed in this publication takes noise reduction measures by adjusting the relative dielectric constant or the relative permeability of an underfilling material charged between the interposer and the motherboard.

Japanese Unexamined Patent Application Publication No. 2012-104776 discloses an invention which aims to enhance high-frequency characteristics by reducing the parasitic inductance of wires used for performing wire bonding in a general quad flat non-leads (QFN) package. In the invention disclosed in this publication, a semiconductor IC chip is disposed at a position displaced from a center area of a die bond region of a lead frame toward one side. This makes it possible to decrease the length of a wire connected to a specific terminal, which may reduce the parasitic inductance.

### BRIEF SUMMARY OF THE INVENTION

The invention disclosed in Japanese Unexamined Patent Application Publication No. 2007-5477 is feasible on the precondition that a specific type of underfilling material is used for mounting a BGA substrate on a motherboard. If an underfilling material is not used or if the type of underfilling material to be used is not changeable, it is not possible to reduce noise.

The invention disclosed in Japanese Unexamined Patent Application Publication No. 2012-104776 aims to decrease the parasitic inductance by modifying the configuration of the semiconductor package itself in a special manner. In this configuration, it does not matter whether or not an underfilling material is used for mounting this semiconductor package on a motherboard or which type of underfilling material is used. However, it is not possible to decrease the lengths of wires connected to all terminals at the same time in a single semiconductor package. Accordingly, by displacing the semiconductor IC chip toward one side, it is possible to reduce the parasitic inductance of wires connected to some terminals, but on the other hand, the lengths of wires connected to some of the other terminals are increased, which sacrifices the characteristics of a part of the semiconductor package concerning such terminals.

It is thus desirable to achieve noise reduction by taking measures other than the use of an underfilling material. It is also desirable to provide a structure which makes it possible to enhance high-frequency characteristics of the entirety of a semiconductor package without sacrificing high-frequency characteristics of a part of the semiconductor package concerning some terminals. It is particularly desirable to reduce the occurrence of harmonic generation when handling high-frequency signals in a semiconductor package including an IC.

Accordingly, it is an object of the present invention to provide a semiconductor package and a semiconductor module in which the occurrence of harmonic generation is reduced.

According to preferred embodiments of the present invention, there is provided a semiconductor package including: a high-output switch IC including an IC top surface having an electrode disposed and an IC bottom surface having no electrode disposed; a connecting terminal formed at a position outside a projection region toward a side portion of the semiconductor package, the projection region being a region projected in a thickness direction of the high-output switch IC; a wire electrically connecting the electrode to the connecting terminal; and a mold resin section covering the IC top surface and the wire and also covers a surface of the connecting terminal to which the wire is connected. A surface of the connecting terminal opposite to the surface to which the wire is connected is not covered with the mold resin section but is exposed. The IC bottom surface is not covered with a metal.

According to preferred embodiments of the present invention, since the IC bottom surface is not covered with a metal, it is possible to reduce the occurrence of harmonic generation.

Other features, elements, characteristics and advantages of the present invention will become more apparent from the following detailed description of preferred embodiments of the present invention with reference to the attached drawings.

### BRIEF DESCRIPTION OF THE SEVERAL VIEWS OF THE DRAWINGS

FIG. 1 is a sectional view of a semiconductor package according to a first embodiment of the invention;

FIG. 2 is a plan view of a lead frame used for fabricating the semiconductor package of the first embodiment;

FIG. 3 illustrates a first step of a manufacturing method for the semiconductor package of the first embodiment;

FIG. 4 illustrates a second step of the manufacturing method for the semiconductor package of the first embodiment;

FIG. 5 illustrates a third step of the manufacturing method for the semiconductor package of the first embodiment;

FIG. 6 illustrates a fourth step of the manufacturing method for the semiconductor package of the first embodiment;

FIG. 7 illustrates a fifth step of the manufacturing method for the semiconductor package of the first embodiment;

FIG. 8 is a sectional view of a first modified example of the semiconductor package of the first embodiment;

FIG. 9 is a sectional view of a second modified example of the semiconductor package of the first embodiment;

FIG. 10 is a partial sectional view of a switch IC suitably used for the semiconductor package of the first embodiment;

FIG. 11 is a sectional view of a semiconductor package according to a second embodiment of the invention;

FIG. 12 is a sectional view of sample 1 used in a first example;

FIG. 13 is a sectional view of sample 2 used in the first example;

FIG. 14 is a sectional view of sample 3 used in the first example;

FIG. 15 is a graph illustrating the results of the first example;

FIG. 16 is a graph illustrating the results of a second example;

FIG. 17 is an assumed circuit when an experiment of a third example is conducted;

FIG. 18 is a first graph illustrating the results of the third example;

FIG. 19 is a second graph illustrating the results of the third example;

FIG. 20 is a graph illustrating the results of a fourth example;

FIG. 21 is a sectional view of a semiconductor package according to a third embodiment of the invention;

FIG. 22 is a sectional view of a semiconductor package according to a fourth embodiment of the invention;

FIG. 23 is a sectional view of a modified example of the semiconductor package of the fourth embodiment;

FIG. 24 is a sectional view of a model in which a metal plate is in contact with the bottom surface of a switch IC;

FIG. 25 is a sectional view of a model in which a metal plate is disposed below a switch IC with an insulating layer therebetween;

FIG. 26 is a sectional view of a semiconductor package according to a fifth embodiment of the invention;

FIG. 27 is a sectional view of sample 7 used in a fifth example;

FIG. 28 is a sectional view of sample 8 used in the fifth example;

FIG. 29 is a sectional view of sample 9 used in the fifth example;

FIG. 30 is a graph illustrating the results of the fifth example;

FIG. 31 is a sectional view of a semiconductor package according to a sixth embodiment of the invention; and

FIG. 32 is a sectional view of a semiconductor package according to a seventh embodiment of the invention.

### DETAILED DESCRIPTION OF THE INVENTION

### First Embodiment

### Configuration

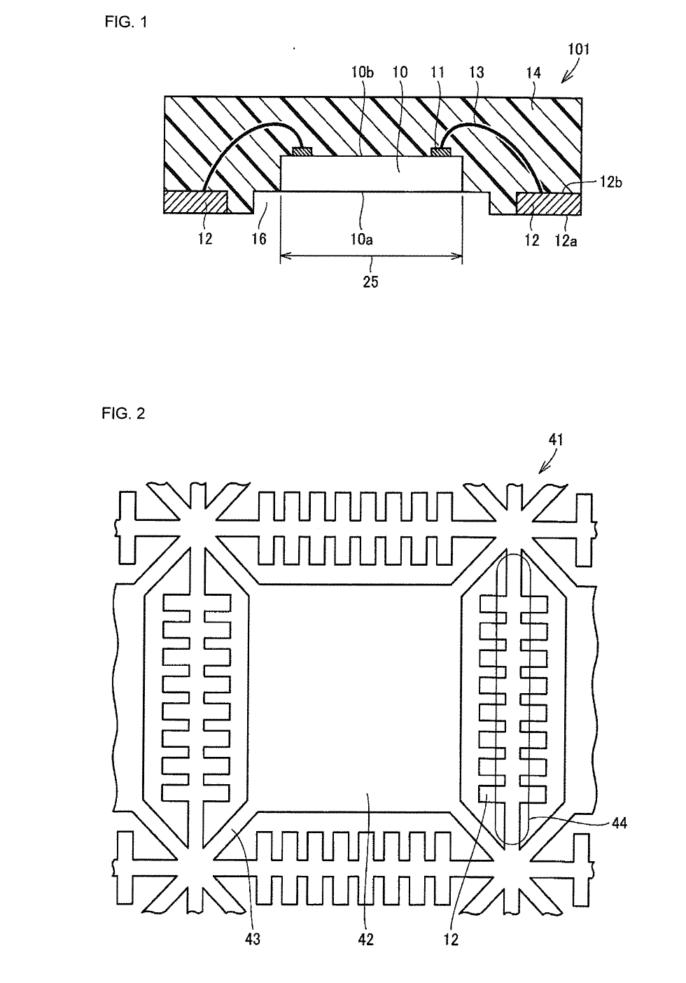

A semiconductor package 101 according to a first embodiment of the present invention will be described below with reference to FIG. 1.

The semiconductor package 101 includes a high-output switch IC 10, connecting terminals 12, wires 13, and a mold resin section 14. The high-output switch IC 10 includes an IC top surface 10b on which electrodes 11 are mounted and an IC bottom surface 10a on which electrodes 11 are not mounted. The connecting terminals 12 are formed at positions outside a projection region 25 toward the side portions of the semiconductor package 101. The projection region 25 is a region projected in the thickness direction of the switch IC 10. The wires 13 electrically connect the electrodes 11 to the connecting terminals 12. The mold resin section 14 covers the IC top surface 10b and the wires 13 and also covers surfaces 12b of the connecting terminals 12 to which the wires 13 are connected. Surfaces 12a of the connecting terminals 12 opposite to the surfaces 12b are not covered with the mold resin section 14 and are exposed. The IC bottom surface 10a is not covered with a metal.

In this specification, “high output” means power of about 26 dBm or higher. A “high-output” switch IC is a switch IC which is resistant to power of about 26 dBm or higher.

In the first embodiment, a silicon IC is used as an example of the switch IC 10. In the first embodiment, a monolithic microwave integrated circuit (MMIC) is used as an example of the switch IC 10.

In the semiconductor package 101 shown in FIG. 1, a recessed portion 16 is formed under the switch IC 10, and the IC bottom surface 10a is exposed to the recessed portion 16. The IC bottom surface 10a is substantially flush with the surfaces 12b of the connecting terminals 12. The configuration of the recessed portion 16 is not restricted to the above-described configuration and is only an example.

### (Operations and Advantages)

In the first embodiment, since the IC bottom surface 10a is not covered with a metal, it is possible to reduce the occurrence of harmonic generation. To verify this effect, the present inventors conducted experiments. The results of the experiments will be discussed later.

### (Manufacturing Method)

The semiconductor package 101 of the first embodiment may be fabricated, for example, by the following manufacturing method.

A lead frame 41 shown in FIG. 2 is first prepared. The lead frame 41 includes a generally square IC mounting section 42 and a plurality of connecting terminals 12. The connecting terminals 12 are disposed separately from the IC mounting section 42 substantially in parallel with the sides of the IC mounting section 42. The IC mounting section 42 is supported by beam-shaped IC-mounting-section support portions 43 from the four directions. The connecting terminals 12 are supported by connecting-terminal support portions 44. The IC-mounting-section support portions 43 and the connecting-terminal support portions 44 are linked to each other. In the lead frame 41, one IC mounting section 42 and its surrounding components form one set. The lead frame 41 comprises a plurality of these sets connected to each other in a matrix shape. The entirety of the lead frame 41 is made of a metal.

The manufacturing method for the semiconductor package 101 will be discussed below by focusing on one IC mounting section 42 and its surrounding components.

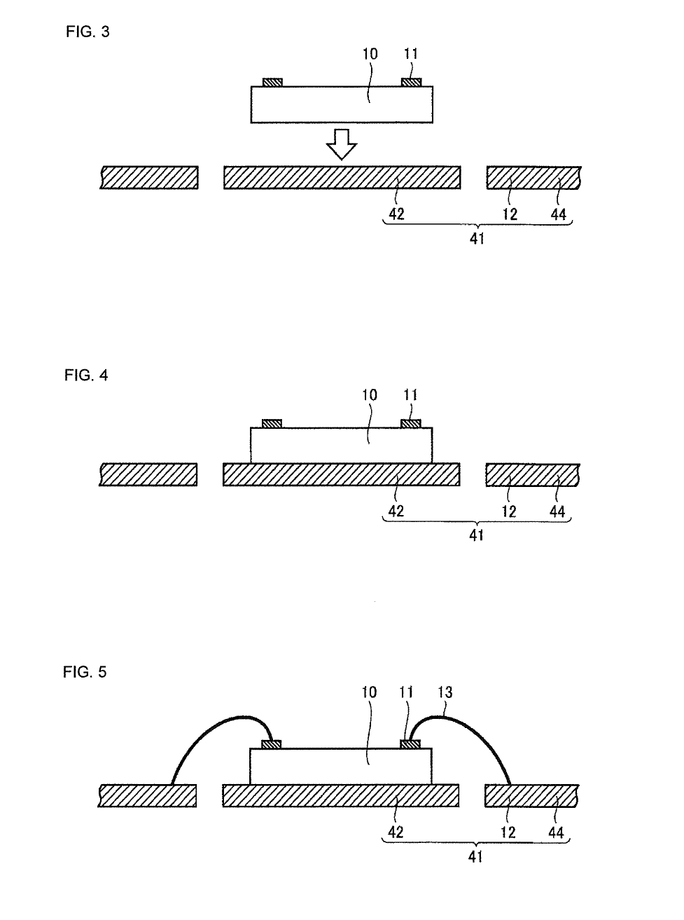

As shown in FIG. 3, the switch IC 10 is mounted on the IC mounting section 42 of the lead frame 41. The switch IC 10 has electrodes 11 on the top surface and has no electrodes 11 on the bottom surface. The bottom surface of the switch IC 10 and the top surface of the IC mounting section 42 may be bonded to each other by using, for example, a silver paste. Instead of a silver paste, a known bonding material may be used. In this manner, as shown in FIG. 4, the switch IC 10 is mounted on the IC mounting section 42. In FIG. 4, a bonding material layer intervening between the switch IC 10 and the IC mounting section 42 is not shown. The bonding material layer is, for example, a silver paste layer.

Then, as shown in FIG. 5, wire bonding is performed. That is, the electrode 11 and the top surface of the connecting terminal 12 are electrically connected to each other by a wire 13. The wire 13 is made of a known material.

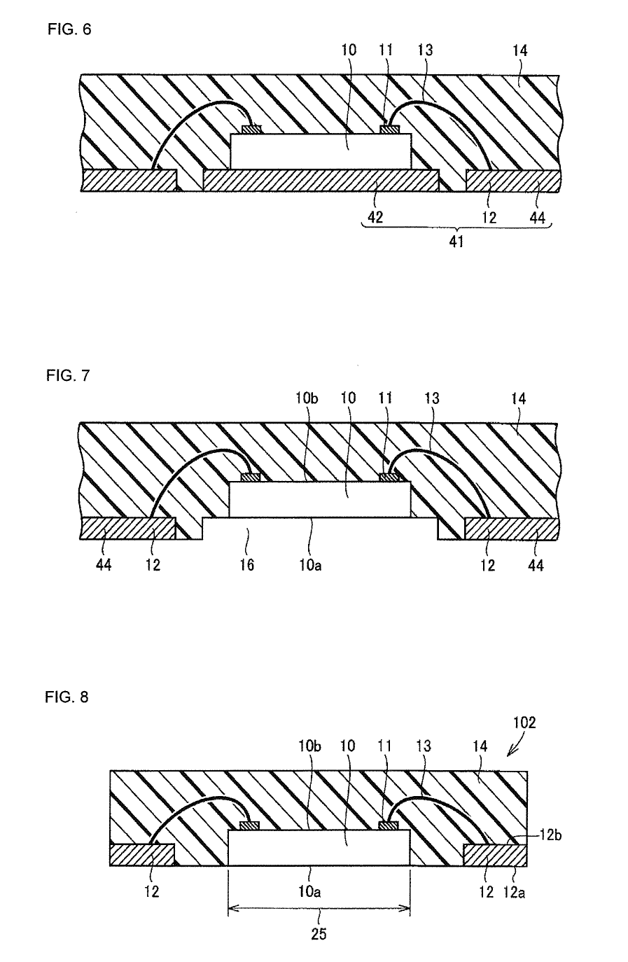

Then, as shown in FIG. 6, the switch IC 10 and the wire 13 are sealed by a resin. In this manner, the mold resin section 14 is formed. Even after the mold resin section 14 is formed, the bottom surface of the connecting terminal 12 is exposed. The top surface of the connecting terminal 12 is covered with the mold resin section 14. At this time point, the bottom surface of the switch IC 10 is covered with the IC mounting section 42.

Then, the IC mounting section 42 is removed. The IC mounting section 42 may be removed as required by a known process. For example, a mask which is exposed only to the portion to be removed on the bottom surface of the structure shown in FIG. 6 is formed, and then, etching is performed, thereby making it possible to selectively remove the IC mounting section 42. As a result, the structure shown in FIG. 7 is formed.

Then, the structure shown in FIG. 7 is cut into individual portions each including the switch IC 10, thereby obtaining the semiconductor package 101 shown in FIG. 1. As a result of cutting the structure shown in FIG. 7 into individual portions, the connecting-terminal support portion 44 is removed, while the connecting terminals 12 supported by the connecting-terminal support portion 44 remain as conductor members supported by the outer edges of the bottom surface of the semiconductor package 101.

The above-described manufacturing method is only an example, and the semiconductor package 101 of the first embodiment may be fabricated by another manufacturing method.

### MODIFIED EXAMPLES

The configuration of the semiconductor package 101 shown in FIG. 1 is only an example, and various modifications may be made by the application of the concept of the first embodiment.

For example, the semiconductor package of the first embodiment may be fabricated as a semiconductor package 102 shown in FIG. 8. In the semiconductor package 102, the IC bottom surface 10a is substantially flush with the bottom surfaces of the connecting terminals 12. The IC bottom surface 10a is not covered with a metal but is exposed. To obtain this configuration, the IC mounting section 42 of the lead frame 41 may be formed at a position lower than the connecting terminals 12, thereby making it possible to implement the semiconductor package 102 shown in FIG. 8.

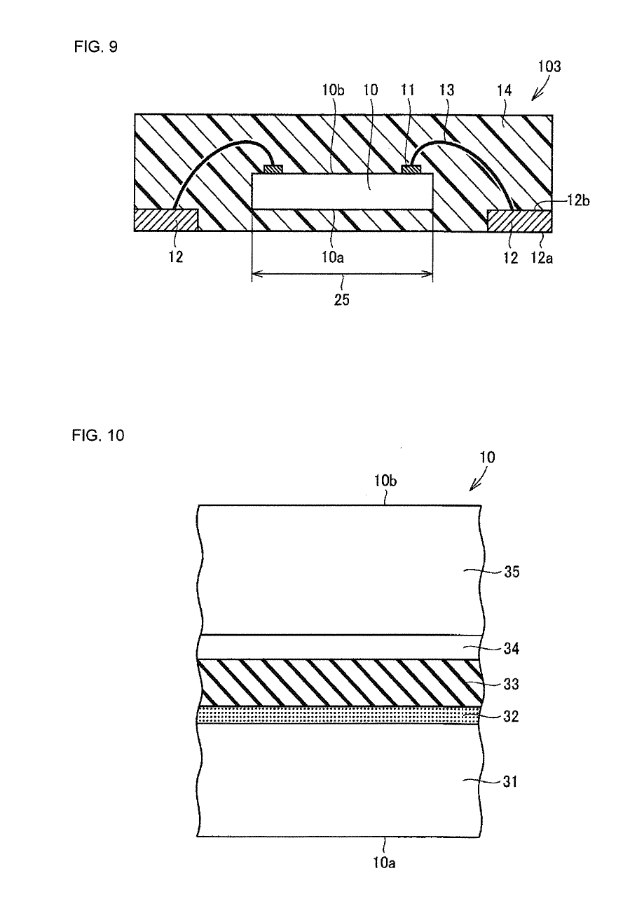

The semiconductor package of the first embodiment may be fabricated as a semiconductor package 103 shown in FIG. 9. In the semiconductor package 103, the bottom surface of the switch IC 10 is covered with the mold resin section 14. To obtain this configuration, after the structure shown in FIG. 1 is fabricated, a mold resin may be additionally charged into the recessed portion 16, thereby making it possible to implement the semiconductor package 103 shown in FIG. 9.

A partial sectional view of the switch IC 10 used in the above-described semiconductor packages 101 through 103 is shown in FIG. 10. However, this configuration is only an example.

As shown in FIG. 10, the switch IC 10 has a multilayered structure in which a high resistivity silicon (Si) layer 31, a highly doped damage implant high-resistivity Si layer 32, an embedded oxide film 33, a Si layer 34, and a structure layer 35 are stacked from the bottom to the top in this order. In this case, a high resistivity Si layer is a layer having a resistivity of 500 Ω·cm or higher. The high resistivity Si layer 31 may be formed by a Si substrate having a resistivity of 500 Ω·cm or higher. The embedded oxide film 33 is, for example, a SiO₂ layer. The structure layer 35 is a layer in which wirings and insulating layers are formed as required. Although the structure layer 35 is formed in a complicated manner, details of the structure layer 35 are not shown in FIG. 10 for the sake of simple representation.

In the above-described semiconductor packages, it is preferable that the IC bottom surface 10a be formed by the high resistivity Si layer 31. By employing this configuration, it is possible to reduce the occurrence of harmonic generation. In the example shown in FIG. 10, the IC bottom surface 10a comprises the high resistivity Si layer 31.

It is preferable that the switch IC 10 be formed by using a silicon on insulator (SOI) technology. By employing this configuration, it is possible to reduce the occurrence of harmonic generation. The SOI is a technology for forming a Si layer on an insulating film. Generally, a SOI substrate is a substrate in which monocrystal silicon is formed on an insulating layer formed on the top surface of a Si substrate. The insulating film is, for example, a SiO₂ layer.

### Second Embodiment

### Configuration

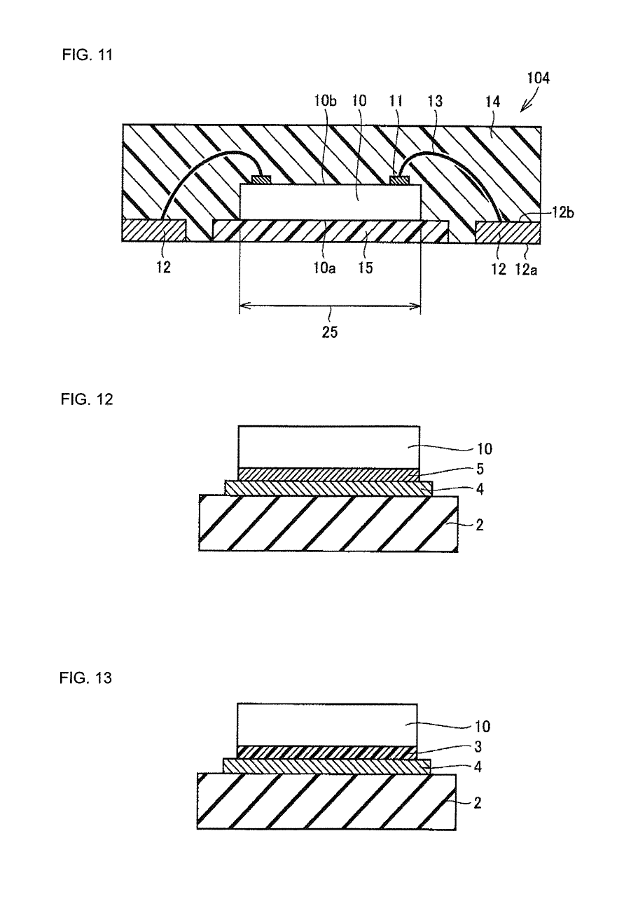

A semiconductor package 104 according to a second embodiment of the present invention will be described below with reference to FIG. 11. The basic configuration of the semiconductor package 104 is similar to that of the semiconductor package 101 of the first embodiment. However, the semiconductor package 104 is different from the semiconductor package 101 in the following point.

In the semiconductor package 104 of the second embodiment, the IC bottom surface 10a is covered with a resin. In the example shown in FIG. 11, a resin layer 15 covers the IC bottom surface 10a.

### (Operations and Advantages)

In the second embodiment, advantages similar to those achieved by the first embodiment can be obtained. The results of experiments conducted for verifying the effects of the second embodiment will be discussed later as first through fourth examples.

In the semiconductor package 104 of the second embodiment, the IC bottom surface 10a is covered with a resin so as to protect the switch IC 10, and thus, the switch IC 10 is less likely to be damaged, compared with the semiconductor packages 101 and 102 of the first embodiment, thereby making it possible to improve the reliability of a semiconductor package as a product.

The semiconductor package 104 may be formed by charging a suitable resin into the recessed portion 16 of the semiconductor package 101 shown in FIG. 1. However, the manufacturing method is not restricted to this method, and may be fabricated by another method.

### (Experiment Results)

The results of experiments conducted by the present inventors will be described below with reference to FIGS. 12 through 16.

### First Example

The present inventors conducted an experiment as a first example for checking how the level of harmonic generation would change by the difference in the configuration of a portion from the bottom surface of a switch IC to an insulating substrate. In the first example, sample 1 through sample 3 having the following configurations were prepared by using a high-power single pole, dual throw (SPDT) switch IC as the switch IC 10.

The sectional view of sample 1 is shown in FIG. 12. In sample 1, a support metal layer 4 is formed on the top surface of an insulating substrate 2. Then, the switch IC 10 is mounted on the top surface of the support metal layer 4 by using a silver paste as a bonding material. After the switch IC 10 has been mounted, the silver paste serves as a silver paste layer 5. The support metal layer 4 is grounded. Since the support metal layer 4 and the switch IC 10 are adjacent to each other with the silver paste layer 5 therebetween, the bottom surface of the switch IC 10 and the support metal layer 4 are electrically connected to each other.

The sectional view of sample 2 is shown in FIG. 13. In sample 2, a support metal layer 4 is formed on the top surface of an insulating substrate 2. Then, the switch IC 10 is mounted on the top surface of the support metal layer 4 by using a resin as a bonding material. After the switch IC 10 has been mounted, the resin serves as a resin layer 3. The support metal layer 4 is grounded. Since the support metal layer 4 and the switch IC 10 are adjacent to each other with the resin layer 3 therebetween, the bottom surface of the switch IC 10 and the support metal layer 4 are insulated from each other.

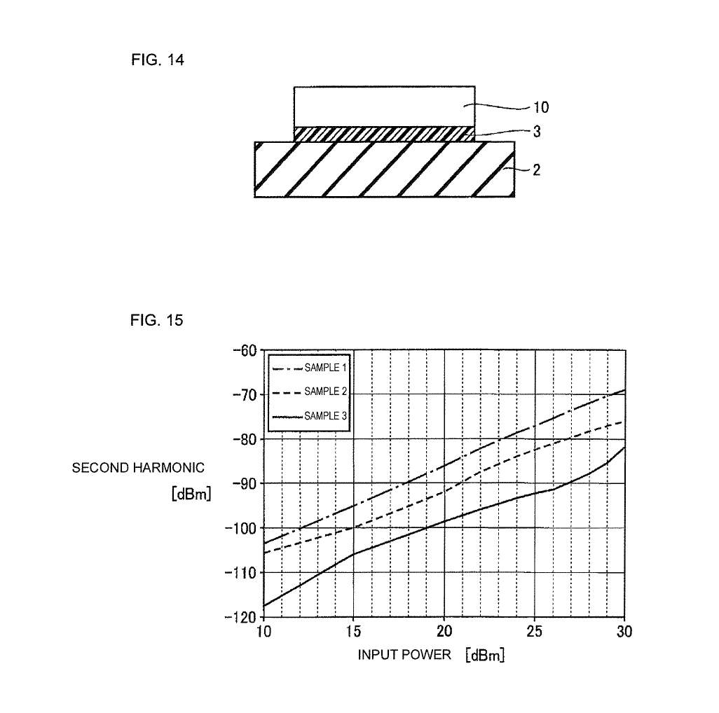

The sectional view of sample 3 is shown in FIG. 14. In sample 3, the switch IC 10 is mounted on the top surface of an insulating substrate 2 by using a resin as a bonding material. After the switch IC 10 has been mounted, the resin serves as a resin layer 3. In this case, the bottom surface of the switch IC 10 is not covered with a metal.

In sample 1 through sample 3, the levels of second harmonic generation were examined by varying the value of the input power. The results are shown in FIG. 15.

FIG. 15 shows that, in the first example, among sample 1 through sample 3, sample 3 exhibits the lowest level of second harmonic generation with respect to any of the values of the input power. Thus, it has been validated that, when a SPDT switch IC is used as the switch IC 10, the occurrence of second harmonic generation is minimized in a configuration in which the bottom surface of the switch IC 10 is not covered with a metal.

### Second Example

Then, the present inventors conducted an experiment as a second example. In the second example, sample 4 through sample 6 having the following configurations were prepared by using a high-power single pole, quadruple throw (SP4T) switch IC as the switch IC 10.

The configuration of sample 4 is the same as that of sample 1, except for the switch IC 10.

The configuration of sample 5 is the same as that of sample 2, except for the switch IC 10.

The configuration of sample 6 is the same as that of sample 3, except for the switch IC 10.

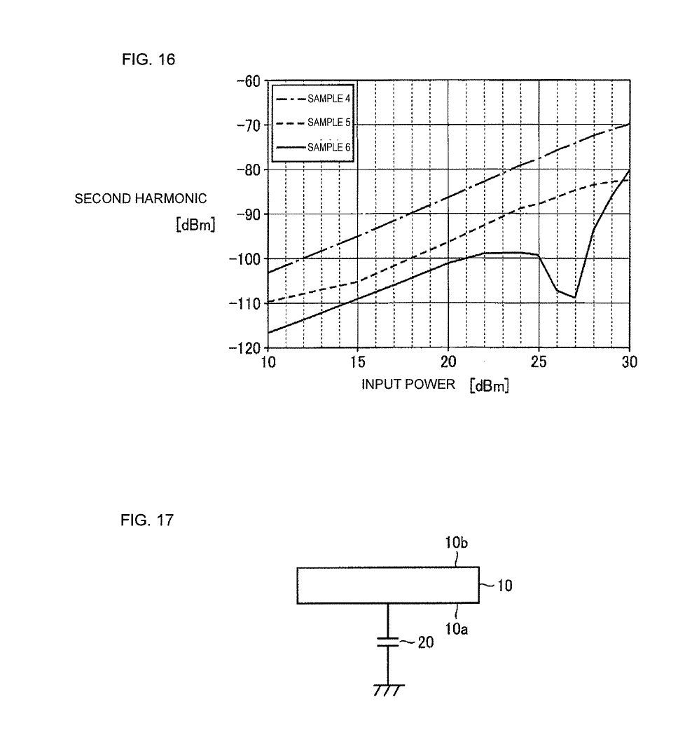

In sample 4 through sample 6, the levels of second harmonic generation were examined by varying the value of the input power. The results are shown in FIG. 16.

FIG. 16 shows that, in the second example, among sample 4 through sample 6, sample 6 exhibits the lowest level of second harmonic generation with respect to most of the values of input power. Thus, it has been validated that, when a SP4T switch IC is used as the switch IC 10, the occurrence of second harmonic generation is minimized in a configuration in which the bottom surface of the switch IC 10 is not covered with a metal.

### Third Example

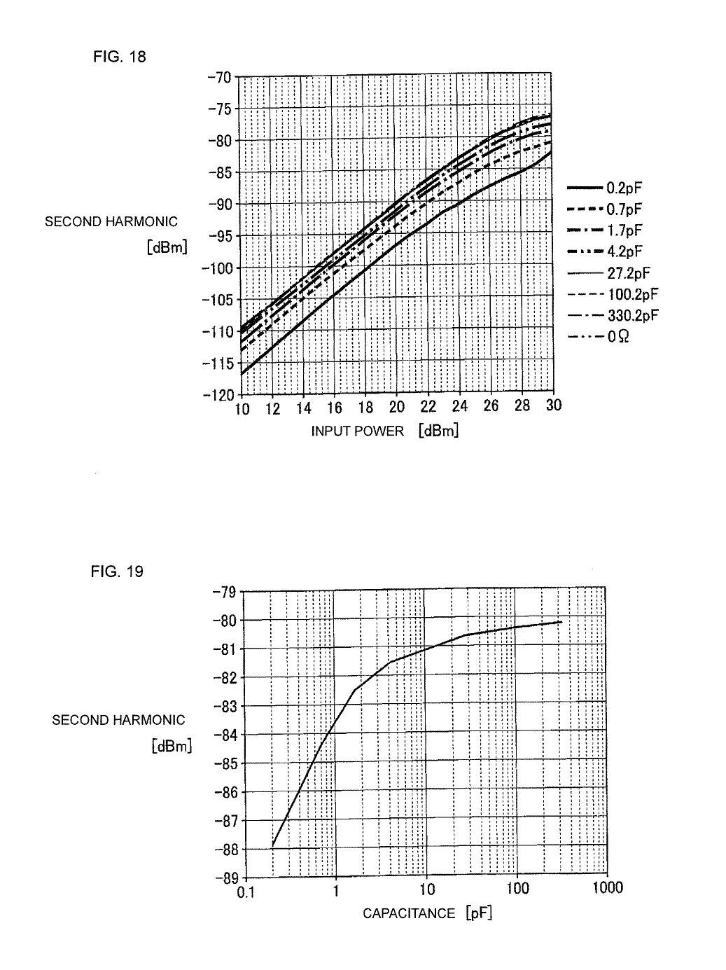

On the basis of the results of the first and second examples, the reason why second harmonic is generated will be considered. It can be assumed that the occurrence of second harmonic generation may be due to the influence of the capacitance formed between a switch IC and a metal member covering the switch IC. Then, the present inventors assumed a pseudo circuit shown in FIG. 17 as a model of a third example. In this circuit, a capacitance 20 is formed between the bottom surface 10a of the switch IC 10 and a ground. As the value of the capacitance 20, the present inventors set several values and used a chip capacitor as required. Then, the levels of second harmonic generation occurring in samples having these capacitance values were examined by varying the value of the input power. The results are shown in FIG. 18. The values expressed by the unit pF at the right side of the graph in FIG. 18 are the values of the capacitance 20. The value “0Ω” represents a configuration in which the IC bottom surface 10a of the switch IC 10 is electrically connected directly to a ground. The value “0.2 pF” represents a configuration in which there is no metal member covering the IC bottom surface 10a of the switch IC 10 and the IC bottom surface 10a of the switch IC 10 is not electrically connected to a ground. In this manner, even if the IC bottom surface 10a of the switch IC 10 is not electrically connected to a ground, a parasitic capacitance of about 0.2 pF is generated between the IC bottom surface 10a of the switch IC 10 and a ground. Accordingly, the minimum value of the capacitance 20 is about 0.2 pF. Concerning the other values of the capacitance 20, the capacitance value is represented by the total value of the parasitic capacitance of 0.2 pF and the value of a chip capacitor. For example, the value “0.7 pF” at the right side of the graph in FIG. 18 represents the experiment result obtained when the capacitance value is about 0.7 pF as a total value of the parasitic capacitance of about 0.2 pF and a capacitance of about 0.5 pF implemented by a chip capacitor.

FIG. 18 shows that, in the third example, as the value of the capacitance 20 is smaller, the level of second harmonic generation is decreased, and that the level of second harmonic generation is minimized when the value of the capacitance 20 is about 0.2 pF. A graph illustrating the level of second harmonic generation obtained by fixing the input power to about 26 dBm and by varying the capacitance value is shown in FIG. 19. This graph shows that, when the input power is constant, the second harmonic generation can be decreased to a smaller level as the capacitance value is decreased.

Based on the above-described results, it has been validated that, in a state in which only a minimal parasitic capacitance is generated between the switch IC 10 and a ground since no metal member is disposed therebetween, the occurrence of second harmonic generation is minimized.

### Fourth Example

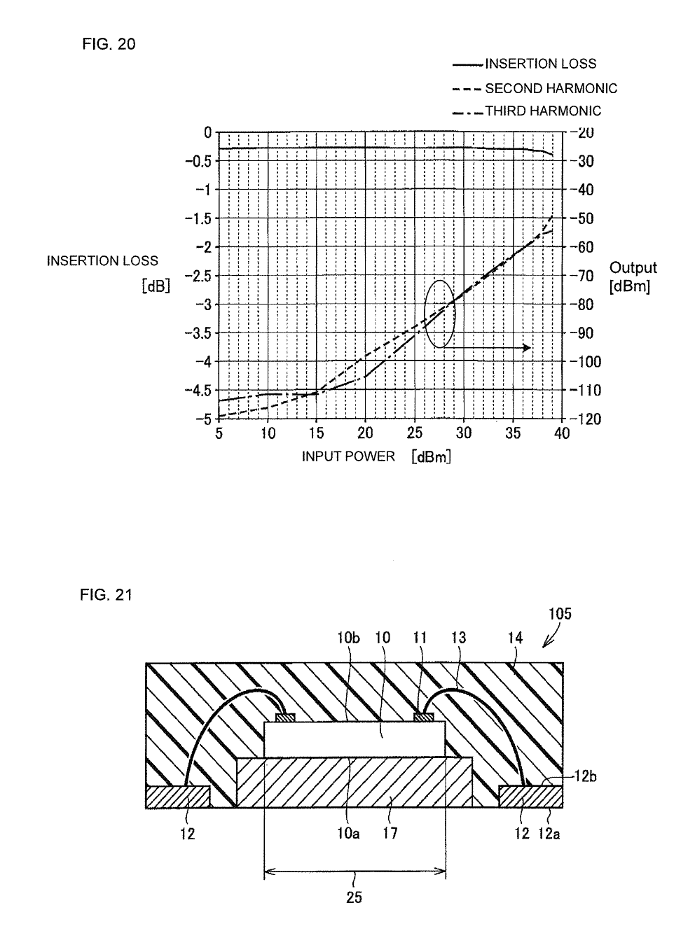

In a general configuration of a known semiconductor package, a metal plate is attached to the bottom surface of a switch IC, and this metal plate is grounded. The switch IC continuously generates heat as it is operating. Thus, in order to prevent the destruction of the switch IC due to the heat, it is necessary to dissipate the heat quickly. The metal plate attached to the bottom surface of the switch IC serves to promote heat dissipation. Accordingly, if a metal plate is removed from the bottom surface of the switch IC, it is necessary to check if there is no problem in terms of heat dissipation. Thus, the present inventors examined a change in the insertion loss by varying the value of the input power in the semiconductor package 104 (see FIG. 11) of the second embodiment. The results are shown in FIG. 20.

FIG. 20 shows that, although the levels of second harmonic generation and third harmonic generation are increased as the value of the input value is higher, the insertion loss itself changes only negligibly, and the switch IC is not destroyed even when the value of the input power increased to as high as about 39 dBm. The results show that, even if a metal plate is removed from the bottom surface of a switch IC, the destruction of the switch IC due to a poor state of heat dissipation does not occur, and thus, the switch IC can be used safely.

### Third Embodiment

### Configuration

A semiconductor package 105 according to a third embodiment of the present invention will be described below with reference to FIG. 21. The basic configuration of the semiconductor package 105 is similar to the semiconductor package 104 of the second embodiment. However, the semiconductor package 105 is different from the semiconductor package 104 in the following point.

In the semiconductor package 105, instead of the resin layer 15 covering the IC bottom surface 10a, a spacer 17 is disposed in contact with the IC bottom surface 10a. The spacer 17 is made of an insulator. The spacer 17 is preferably thicker than the connecting terminal 12.

### (Operations and Advantages)

In the third embodiment, advantages similar to or even better than those achieved by the second embodiment can be obtained. A thicker spacer 17 is more preferable. The reason for this will be discussed later. The material for the spacer 17 is, for example, gallium arsenide (GaAs). As the relative dielectric constant of the spacer 17 is smaller, it is more preferable.

### Fourth Embodiment

### Configuration

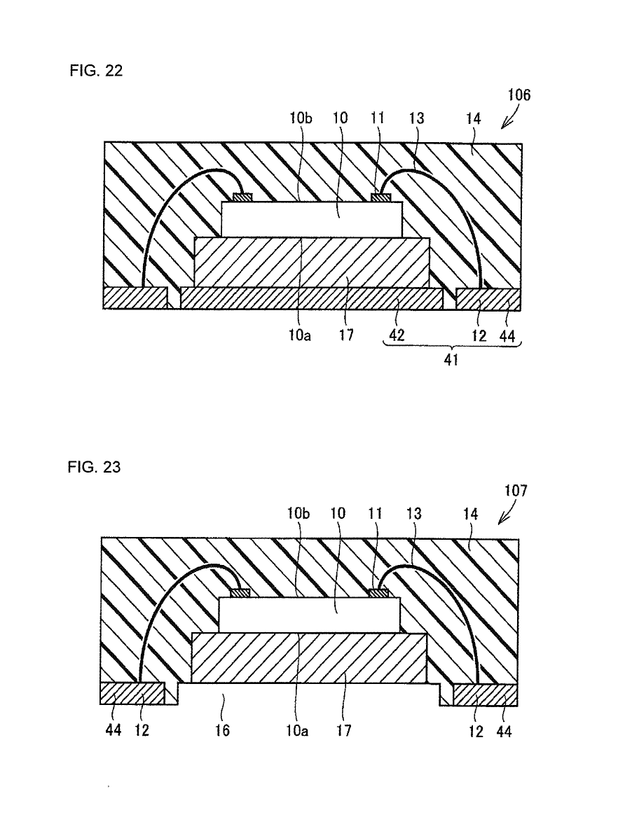

A semiconductor package 106 according to a fourth embodiment of the present invention will be described below with reference to FIG. 22. The basic configuration of the semiconductor package 106 is similar to the semiconductor package 105 of the third embodiment. However, the semiconductor package 106 is different from the semiconductor package 105 in the following point.

In the semiconductor package 106, the IC mounting section 42, which is a part of the lead frame 41, is disposed under the spacer 17 which abuts the IC bottom surface 10a.

### (Operations and Advantages)

In the fourth embodiment, advantages similar to those of the third embodiment can be obtained. The reason for this will be discussed later. In the fourth embodiment, the IC mounting section 42, which is a part of the lead frame 41, is disposed under the switch IC 10. However, the IC mounting section 42 is disposed not essential. Or rather it is preferable not to use the IC mounting section 42.

That is, it is more preferable that, as in a modified example of the fourth embodiment, the IC mounting section 42 be removed, as in a semiconductor package 107 shown in FIG. 23. In the semiconductor package 107, a recessed portion 16 is formed below the spacer 17. The depth of the recessed portion 16 is the same as the thickness of the connecting terminal 12. This configuration may be obtained in the following manner. After a structure, such as the semiconductor package 106, has been formed by using the lead frame 41, the IC mounting section 42, which is a part of the lead frame 41, is removed by means of etching.

The principle of the third and fourth embodiments will be explained below.

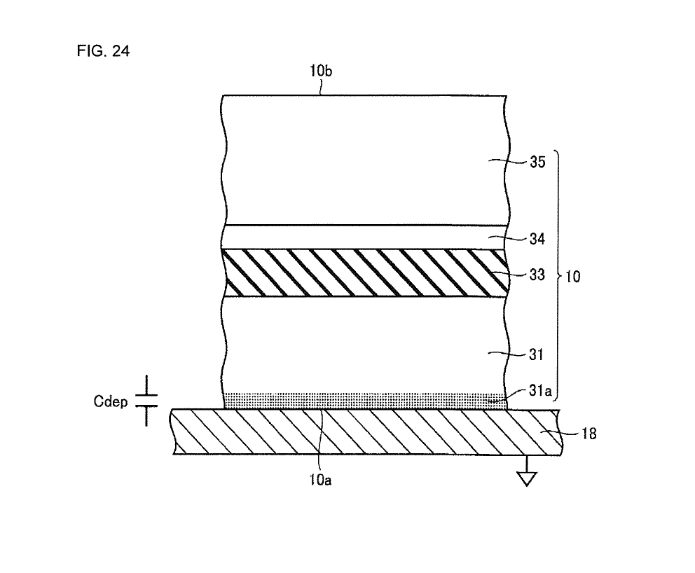

As the basic configuration, a model shown in FIG. 24 will be considered in which a metal plate 18 is disposed under the switch IC 10 in contact with the IC bottom surface 10a of the switch IC 10 and the metal plate 18 is grounded. The model shown in FIG. 24 corresponds to a metal semiconductor (MS) junction.

As shown in FIG. 24, a depletion layer 31a is generated near the bottom surface of the high resistivity Si layer 31 included in the switch IC 10. The thickness of the depletion layer 31a varies in accordance with the magnitude of the applied voltage. Due to the presence of the depletion layer 31a, a depletion layer capacitance C_{dep} is generated.

The capacitance C_{MS} between the high resistivity Si layer 31 and the metal plate 18 is equal to the depletion layer capacitance C_{dep}. The depletion layer capacitance C_{dep} has voltage dependency characteristics, and is likely to cause distortion, such as harmonics. Since the capacitance C_{MS} is equal to the depletion layer capacitance C_{dep}, distortion is likely to occur.

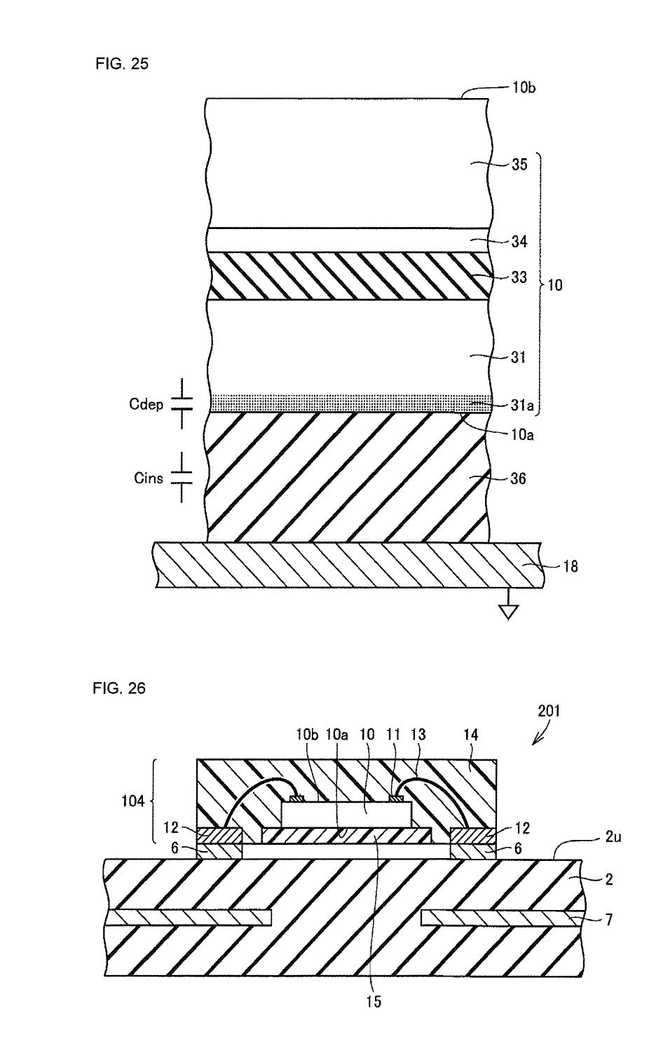

As a configuration corresponding to one of the second, third, and fourth embodiments, a model shown in FIG. 25 will be considered. In the configuration shown in FIG. 25, an insulating layer 36 is disposed between the metal plate 18 and the high resistivity Si layer 31. As in the model shown in FIG. 24, the thickness of the depletion layer 31a varies in accordance with the magnitude of the applied voltage. The model shown in FIG. 25 corresponds to a metal insulator semiconductor (MIS) junction. The metal plate 18 is a virtual metal plate representing the presence of a certain conductor positioned below the switch IC 10.

In the model shown in FIG. 25, due to the presence of the depletion layer 31a, a depletion layer capacitance C_{dep} is generated, and due to the presence of the insulating layer 36, an insulator capacitance Cᵢₙₛ is generated. The capacitance C_{MS} between the high resistivity Si layer 31 and the metal plate 18 is represented by a combined capacitance of the depletion layer capacitance C_{dep} and the insulator capacitance Cᵢₙₛ. Since the capacitance C_{MS} can be considered as a total capacitance of the two capacitances C_{dep} and Cᵢₙₛ connected in series with each other, it is expressed by the following equation.

C_{MS}=C_{dep}Cᵢₙₛ/(C_{dep}+Cᵢₙₛ)

If it is assumed that C_{dep}>>Cᵢₙₛ, C_{MS}≈Cᵢₙₛ is established. Accordingly, the presence of the depletion layer capacitance C_{dep} can be ignored, and the voltage dependency is substantially eliminated. As a result, the occurrence of harmonic distortion can be reduced.

Upon comparing the two models shown in FIGS. 24 and 25, it is seen that the presence of the insulating layer 36 intervening between the depletion layer 31a of the high resistivity Si layer 31 and the grounded virtual metal plate 18 contributes to reducing the occurrence of harmonic distortion. As discussed above, it is assumed that the insulator capacitance Cᵢₙₛ is much smaller than the depletion layer capacitance C_{dep}. A thicker insulating layer 36 is more effective for reducing the insulator capacitance Cᵢₙₛ. In the third and fourth embodiments, the spacer 17 made of an insulator is disposed under the switch IC 10, and the spacer 17 corresponds to the insulating layer 36. By the provision of the spacer 17, insulator capacitance Cᵢₙₛ can be made much smaller than the depletion layer capacitance C_{dep}, thereby making it possible to reduce the occurrence of harmonic distortion. This is the reason why a thicker spacer 17 is more preferable. The material for the insulating layer 36 and the spacer 17 may be a certain type of resin, for example, glass epoxy.

### Fifth Embodiment

### Configuration

A semiconductor module 201 according to a fifth embodiment of the present invention will be described below with reference to FIG. 26.

The semiconductor module 201 includes an insulating substrate 2 and the semiconductor package 104. The insulating substrate 2 includes a principal front surface 2u and a sheet-like conductor 7 extending in a direction substantially parallel with the principal front surface 2u and located inwardly at a height position of the insulating substrate 2 away from the principal front surface 2u. The semiconductor package 104 is mounted on the principal front surface 2u of the insulating substrate 2 via the connecting terminals 12. The sheet-like conductor 7 is disposed outside the projection region, which is projected in the thickness direction of the switch IC 10. The connecting terminals 12 of the semiconductor package 104 are connected to pad electrodes 6, which are disposed on the principal front surface 2u of the insulating substrate 2 in advance.

### (Operations and Advantages)

In the fifth embodiment, the sheet-like conductor 7 disposed within the insulating substrate 2 is formed outside the projection region, which is projected in the thickness direction of the switch IC 10 included in the semiconductor package 104, thereby making it possible to reduce the occurrence of harmonic generation. To verify this effect, the present inventors conducted an experiment as a fifth example. Details of the fifth example will be discussed later.

In the fifth embodiment, the semiconductor module 201 includes the semiconductor package 104 as an example. However, any one of the semiconductor packages 101 through 107 discussed in the first through fourth embodiments may be mounted on the insulating substrate 2.

### Fifth Example

The present inventors prepared sample 7 through sample 9 having the following configurations by using a dual pole, 12 throw (DP12T) switch IC as the switch IC 10.

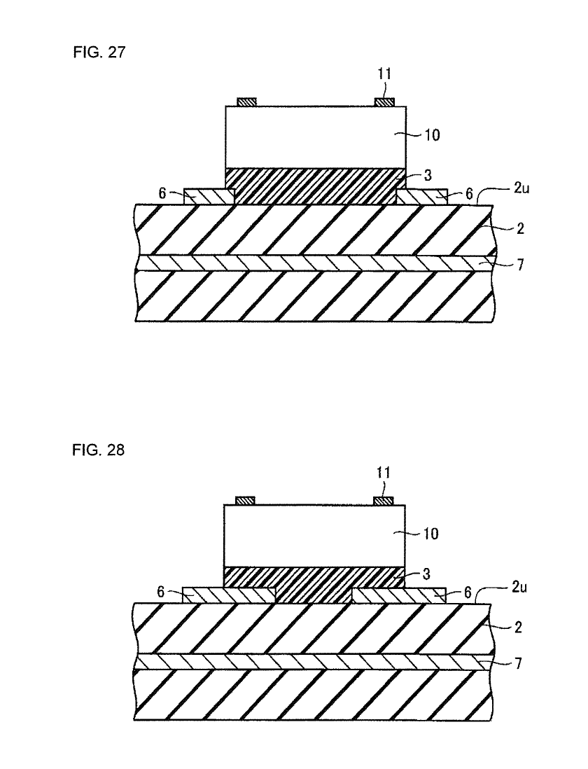

The sectional view of sample 7 is shown in FIG. 27. Pad electrodes 6 are formed on the principal front surface 2u of the insulating substrate 2. The switch IC 10 is bonded to the principal front surface 2u with the resin layer 3 therebetween. The pad electrodes 6 are disposed outside the most part of the bottom surface of the switch IC 10. As shown in FIG. 27, in sample 7, mere small portions of the pad electrodes 6 overlap the bottom surface of the switch IC 10.

The sectional view of sample 8 is shown in FIG. 28. In sample 8, the pad electrodes 6 formed on the principal front surface 2u of the insulating substrate 2 extend farther toward the center than the pad electrodes 6 of sample 7. Accordingly, the areas of the pad electrodes 6 are wider, and conversely, the portion of the bottom surface of the switch IC 10 which does not overlap the pad electrodes 6 is narrower. The portion of the bottom surface of the switch IC 10 which does not overlap the pad electrodes 6 is only a central portion, and the area of such a portion is about half of the bottom surface of the switch IC 10.

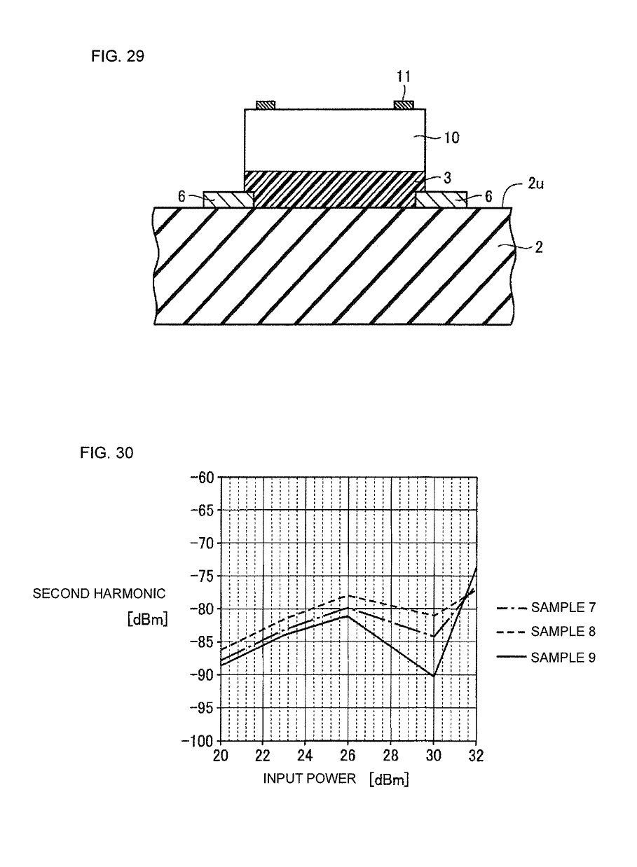

The sectional view of sample 9 is shown in FIG. 29. In sample 9, the arrangement of the pad electrodes 6 is the same as that of sample 7. In sample 7 and sample 8, a sheet-like conductor 7 is disposed within the insulating substrate 2 and extends continuously including the projection region of the switch IC 10. In contrast, in sample 9, there is no sheet-like conductor 7 disposed within the insulating substrate 2.

In sample 7 through sample 9, the levels of second harmonic generation were examined by varying the value of the input power. The results are shown in FIG. 30.

FIG. 30 shows that, in the fifth example, among sample 7 through sample 9, sample 9 exhibits the lowest level of second harmonic generation with respect to most of the values of input power. In particular, when the input power is about 30 dBm, there is a conspicuous difference in the level of second harmonic generation between sample 9 and samples 7 and 8. Thus, it has been validated from FIG. 30 that the occurrence of second harmonic generation can be reduced to a smaller level in a configuration in which a sheet-like conductor 7 is not disposed within the insulating substrate 2 at a position at which it is superposed on the switch IC 10, as viewed from above, than in a configuration in which a sheet-like conductor 7 is disposed at such a position.

### Sixth Embodiment

The semiconductor module 201 (see FIG. 26) of the fifth embodiment has only one layer of the sheet-like conductor 7 within the insulating substrate 2. However, the present invention does not exclude a case in which a sheet-like conductor other than the sheet-like conductor 7 is disposed within the insulating substrate 2. That is, within the insulating substrate 2, a plurality of sheet-like conductors may be disposed or a sheet-like conductor other than the sheet-like conductor 7 may be disposed.

### (Configuration)

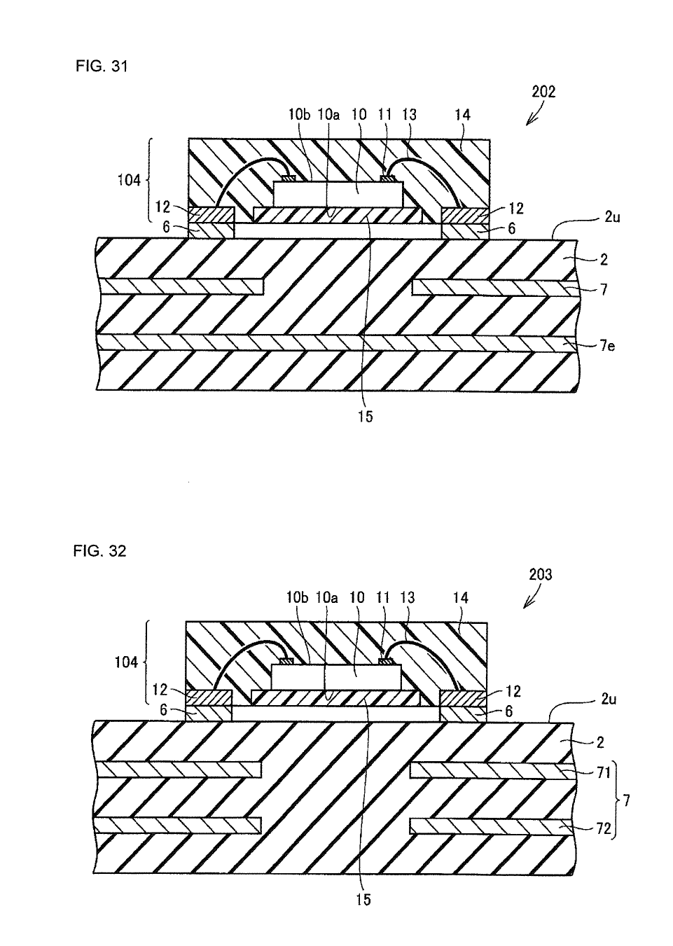

A semiconductor module 202 according to a sixth embodiment of the present invention will be described below with reference to FIG. 31. In the semiconductor module 202, within a single insulating substrate 2, sheet-like conductors 7 and 7e are separately disposed substantially parallel with each other. In the semiconductor module 202, the sheet-like conductor 7 is disposed closer to the principal front surface 2u than the sheet-like conductor 7e within the insulating substrate 2. As discussed in the fifth embodiment, the sheet-like conductor 7 is disposed outside the projection region, which is projected in the thickness direction of the switch IC 10. On the other hand, the sheet-like conductor 7e is not always outside the projection region. In the example shown in FIG. 31, the sheet-like conductor 7e extends continuously including the projection region of the switch IC 10.

### (Operations and Advantages)

In the sixth embodiment, advantages similar to those of the fifth embodiment can be obtained to a certain degree.

In the semiconductor module 202 of the sixth embodiment, two layers of sheet-like conductors are disposed within the insulating substrate 2 as an example. However, the number of layers of sheet-like conductors is not restricted to two, and more layers of sheet-like conductors may be disposed as long as the sheet-like conductor positioned closest to the principal front surface 2u satisfies the conditions set for the sheet-like conductor 7 discussed in the fifth embodiment.

### Seventh Embodiment

### Configuration

A semiconductor module 203 according to a seventh embodiment of the present invention will be described below with reference to FIG. 32. The basic configuration of the semiconductor module 203 is similar to the semiconductor modules 201 and 202 of the fifth and sixth embodiments, respectively. The semiconductor module 203 is different from the semiconductor modules 201 and 202 in the following points.

In the semiconductor module 203, a sheet-like conductor 7 comprises a set of a plurality of sheet-like conductor elements 71 and 72. The plurality of sheet-like conductor elements 71 and 72 are disposed substantially in parallel with each other such that they are superposed on each other, as viewed from above, at different height positions of the insulating substrate 2. The plurality of sheet-like conductor elements 71 and 72 are all disposed outside the projection region, which is projected in the thickness direction of the switch IC 10.

### (Operations and Advantages)

In the seventh embodiment, the sheet-like conductor 7 disposed within the insulating substrate 2 comprises a set of the plurality of sheet-like conductor elements 71 and 72. The plurality of sheet-like conductor elements 71 and 72 are all disposed outside the projection region, which is projected in the thickness direction of the switch IC 10, thereby making it possible to reduce the occurrence of harmonic generation.

If it is desired that the sheet-like conductor 7 serves to shield the region other than the projection region of the switch IC 10, the shielding effect is more reliably obtained if the sheet-like conductor 7 comprises a set of the plurality of sheet-like conductor elements 71 and 72, as shown in FIG. 32.

In the fifth through seventh embodiments, the semiconductor modules 201 through 203 each include the semiconductor package 104 as an example. However, any one of the semiconductor packages 101 through 107 discussed in the first through fourth embodiments may be mounted on the insulating substrate 2.

In the semiconductor modules 201 through 203 discussed in the fifth through seventh embodiments, it is not essential, but it is preferable that the sheet-like conductor 7 be grounded. That is, the sheet-like conductor 7 is preferably a ground electrode.

In the seventh embodiment, the sheet-like conductor 7 includes two sheet-like conductor elements 71 and 72. However, the number of sheet-like conductor elements forming the sheet-like conductor 7 is not restricted to two, and may be more.

Some of the above-described embodiments may be combined as required.

While preferred embodiments of the invention have been described above, it is to be understood that variations and modifications will be apparent to those skilled in the art without departing from the scope and spirit of the invention. The scope of the invention, therefore, is to be determined solely by the following claims.

What is claimed is:

1. A semiconductor package comprising:
a high-output switch integrated circuit including an integrated circuit top surface having an electrode disposed and an integrated circuit bottom surface having no electrode disposed;
a connecting terminal formed at a position outside a projection region toward a side portion of the semiconductor package, the projection region being a region projected in a thickness direction of the high-output switch integrated circuit;
a wire electrically connecting the electrode to the connecting terminal; and
a mold resin section covering the integrated circuit top surface and the wire and also covering a surface of the connecting terminal to which the wire is connected, wherein
a surface of the connecting terminal opposite to the surface to which the wire is connected is not covered with the mold resin section but is exposed, and
the integrated circuit bottom surface is not covered with a metal.

2. The semiconductor package according to claim 1, wherein the integrated circuit bottom surface comprises a high resistivity silicon layer.

3. The semiconductor package according to claim 1, wherein the integrated circuit bottom surface is covered with a resin.

4. The semiconductor package according to claim 1, wherein the high-output switch integrated circuit is formed by using a silicon-on-insulator technology.

5. A semiconductor module comprising:
an insulating substrate including a principal front surface and a sheet-like conductor extending in a direction substantially parallel with the principal front surface and located inwardly at a height position of the insulating substrate away from the principal front surface; and
the semiconductor package according to claim 1 being mounted on the principal front surface of the insulating substrate via the connecting terminal,
wherein the sheet-like conductor is disposed outside the projection region.

6. The semiconductor module according to claim 5, wherein the sheet-like conductor comprises a set of a plurality of sheet-like conductor elements, and the plurality of sheet-like conductor elements are disposed substantially in parallel with each other such that the plurality of sheet-like conductor elements are superposed on each other, as viewed from above, at different height positions of the insulating substrate, and the plurality of sheet-like conductor elements are all disposed outside the projection region.

7. The semiconductor module according to claim 5, wherein the sheet-like conductor is grounded.

8. The semiconductor package according to claim 2, wherein the integrated circuit bottom surface is covered with a resin.

9. The semiconductor package according to claim 2, wherein the high-output switch integrated circuit is formed by using a silicon-on-insulator technology.

10. The semiconductor package according to claim 3, wherein the high-output switch integrated circuit is formed by using a silicon-on-insulator technology.

11. A semiconductor module comprising:
an insulating substrate including a principal front surface and a sheet-like conductor extending in a direction substantially parallel with the principal front surface and located inwardly at a height position of the insulating substrate away from the principal front surface; and
the semiconductor package according to claim 2 being mounted on the principal front surface of the insulating substrate via the connecting terminal,
wherein the sheet-like conductor is disposed outside the projection region.

12. A semiconductor module comprising:
an insulating substrate including a principal front surface and a sheet-like conductor extending in a direction substantially parallel with the principal front surface and located inwardly at a height position of the insulating substrate away from the principal front surface; and
the semiconductor package according to claim 3 being mounted on the principal front surface of the insulating substrate via the connecting terminal,
wherein the sheet-like conductor is disposed outside the projection region.

13. A semiconductor module comprising:
an insulating substrate including a principal front surface and a sheet-like conductor extending in a direction substantially parallel with the principal front surface and located inwardly at a height position of the insulating substrate away from the principal front surface; and
the semiconductor package according to claim 4 being mounted on the principal front surface of the insulating substrate via the connecting terminal,
wherein the sheet-like conductor is disposed outside the projection region.

14. The semiconductor module according to claim 6, wherein the sheet-like conductor is grounded.
